(19) United States
(12) Patent Application Publication
(10) Pub. No.: US 2025/0036840 A1
(43) Pub. Date: Jan. 30, 2025

(54) PARAMETERIZED IP ALGORITHM FOR POWER REDUCTION ACROSS A CHIP HIERARCHY

(71) Applicant: INTERNATIONAL BUSINESS MACHINES CORPORATION, ARMONK, NY (US)

(72) Inventors: AMIT BIPINBHAI PATEL, BENGALURU (IN); KRISHNAN MOHAN, BANGALORE (IN); ANANTH NAG RAJA DARLA, BANGALORE (IN); RAJESH VEERABHADRAIAH, TUMKUR (IN); VISHAL SINDHE, BANGALORE (IN)

(21) Appl. No.: 18/357,380

(22) Filed: Jul. 24, 2023

(51) Int. Cl. G06F 30/3323; G06F 30/337

(52) U.S. Cl. CPC G06F 30/3323; G06F 30/337

(57) ABSTRACT

Providing a parameterized IP algorithm for power reduction across a chip hierarchy including for each input pin at a chip hierarchy level, determining a parameterized diode value only for an indication of an antenna violation, wherein a parameterized diode is scaled to protect a gate; and enabling the parameterized diode with the parameterized diode value. Providing a parameterized IP algorithm also includes placing a placeholder parameterized diode for each input pin; for each IP, converting the IP into a parameterized IP; and upon a determination of no antenna violation, disabling the parameterized diode.

### BACKGROUND

### Field of the Disclosure

The field of the disclosure is power management, or, more specifically, methods, apparatus, and products for providing a parameterized IP algorithm for power reduction across a chip hierarchy.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago, with more transistors on smaller packages.

The most sensitive component of a MOS (metal-oxide-semiconductor) or MOSFET (field effect transistor) is the gate oxide. During the construction of an IC (integrated circuit), special care must be taken to safeguard it from damage both throughout the fabrication process and during the functioning of the IC. An unwanted impact that can arise throughout the actual manufacturing process is the antenna effect, also known as plasma-induced gate-oxide damage or plasma-induced damage. Protecting the gate during manufacture and use while reducing power consumption is desirable.

### SUMMARY

Methods, apparatuses, and products for providing a parameterized intellectual property (IP) algorithm for power reduction across a chip hierarchy according to various embodiments are disclosed. Providing a parameterized IP algorithm for power reduction across a chip hierarchy can include: for each input pin at a chip hierarchy level, determining a parameterized diode value only for an indication of an antenna violation, wherein a parameterized diode is scaled to protect a gate; and enabling the parameterized diode with the parameterized diode value. Providing a parameterized IP algorithm for power reduction across a chip hierarchy can further include: placing a placeholder parameterized diode for each input pin; for each IP, converting the IP into a parameterized IP; and upon a determination of no antenna violation, disabling the parameterized diode.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1A is a diagram of an example chip configured for providing a parameterized IP algorithm for power reduction across a chip hierarchy in accordance with embodiments of the present disclosure.

FIG. 1B is a top view of a diagram of an example chip configured for providing a parameterized IP algorithm for power reduction across a chip hierarchy in accordance with embodiments of the present disclosure.

FIG. 1C is a diagram of an example circuit configured for providing a parameterized IP algorithm for power reduction across a chip hierarchy in accordance with embodiments of the present disclosure.

FIG. 2A is a diagram of an example chip configured for providing a parameterized IP algorithm for power reduction across a chip hierarchy in accordance with embodiments of the present disclosure.

FIG. 2B is a diagram of an example chip configured for providing a parameterized IP algorithm for power reduction across a chip hierarchy in accordance with embodiments of the present disclosure.

FIG. 2C is a diagram of an example circuit configured for providing a parameterized IP algorithm for power reduction across a chip hierarchy in accordance with embodiments of the present disclosure.

FIG. 3A is a block diagram of an example chip for providing a parameterized IP algorithm for power reduction across a chip hierarchy in accordance with embodiments of the present disclosure.

FIG. 3B is a block diagram of an example chip hierarchy for providing a parameterized IP algorithm for power reduction across a chip hierarchy in accordance with embodiments of the present disclosure.

FIG. 4 is a block diagram of an example computing system configured for providing a parameterized IP algorithm for power reduction across a chip hierarchy in accordance with embodiments of the present disclosure.

FIG. 5A is a diagram of an example chip configured for providing a parameterized IP algorithm for power reduction across a chip hierarchy in accordance with embodiments of the present disclosure.

FIG. 5B is a diagram of an example chip configured for providing a parameterized IP algorithm for power reduction across a chip hierarchy in accordance with embodiments of the present disclosure.

FIG. 5C is a diagram of an example chip configured for providing a parameterized IP algorithm for power reduction across a chip hierarchy in accordance with embodiments of the present disclosure.

FIG. 6A is a diagram of an example chip configured for providing a parameterized IP algorithm for power reduction across a chip hierarchy in accordance with embodiments of the present disclosure.

FIG. 6B is a diagram of an example chip configured for providing a parameterized IP algorithm for power reduction across a chip hierarchy in accordance with embodiments of the present disclosure.

FIG. 6C is a diagram of an example chip configured for providing a parameterized IP algorithm for power reduction across a chip hierarchy in accordance with embodiments of the present disclosure.

FIG. 7 is a flowchart of an example method for providing a parameterized IP algorithm for power reduction across a chip hierarchy according to some embodiments of the present disclosure.

FIG. 8 is a block diagram of an example chip hierarchy for providing a parameterized IP algorithm for power reduction across a chip hierarchy in accordance with embodiments of the present disclosure.

FIG. 9 is a flowchart of an example method for providing a parameterized IP algorithm for power reduction across a chip hierarchy according to some embodiments of the present disclosure.

FIG. 10 is a flowchart of an example method for providing a parameterized IP algorithm for power reduction across a chip hierarchy according to some embodiments of the present disclosure.

FIG. 11 is a flowchart of an example method for providing a parameterized IP algorithm for power reduction across a chip hierarchy according to some embodiments of the present disclosure.

### DETAILED DESCRIPTION

In VLSI (very large-scale integration) circuit technology, the term “antenna effect” refers to the charge collecting effect, not to the antenna device. A large quantity of charge is often induced during plasma etching and other procedures. The antenna effect in VLSI is a phenomenon that can harm the gate oxide of MOS transistors during the fabrication process.

If a conducting material or wire is linked to the device's gate, the wire acts as an antenna, inducing a considerable amount of charge, and diodes produced by drain and source diffusion layers can conduct a significant amount of current. The antenna effect causes gate failure or I-V characteristics to deteriorate. Changing threshold voltage; lower device life expectancy; and increased gate leakage are some of the issues that might arise. Antenna guidelines have been established in order to prevent these effects. A solution is to attach the diode to the wire and establish a discharge path during the etching process.

In more detail, an antenna violation occurs when the antenna ratio exceeds a value specified in a Process Design Kit (PDK). The antenna ratio is the ratio of the gate area to the gate oxide area. The amount of charge collection is determined by the area/size of the conductor (gate area). Connecting reverse biased diodes near the gate input when a net is violated gives a discharge channel to the substrate, saving the transistor's gate. The addition of a diode increases the area as well as the capacitance, resulting in a delay increase. Insertion of a diode increases capacitance which is directly proportional to power consumption.

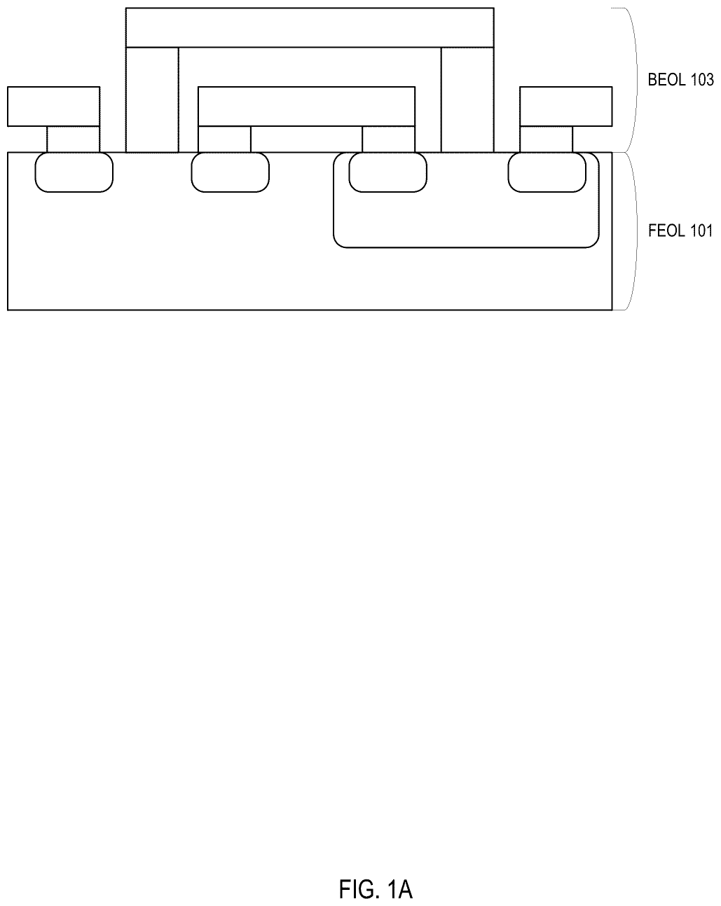

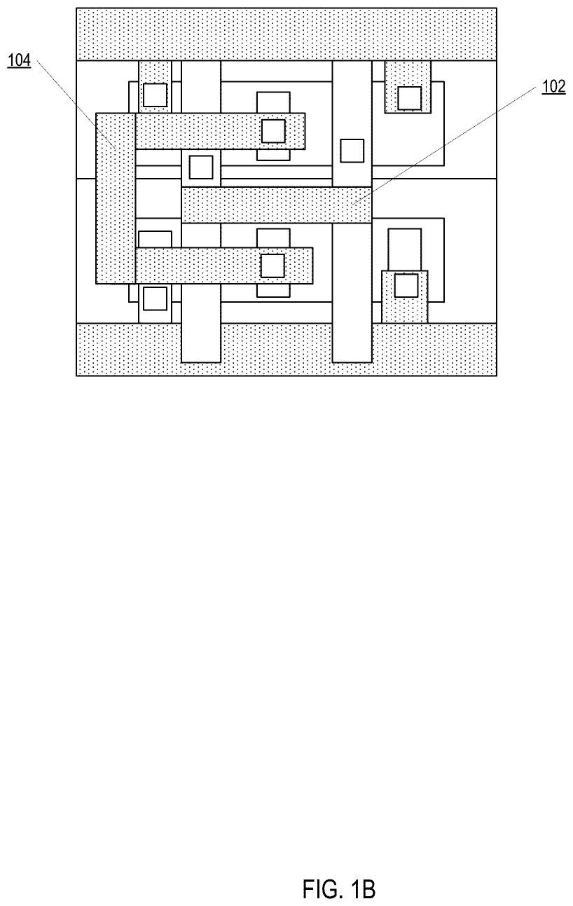

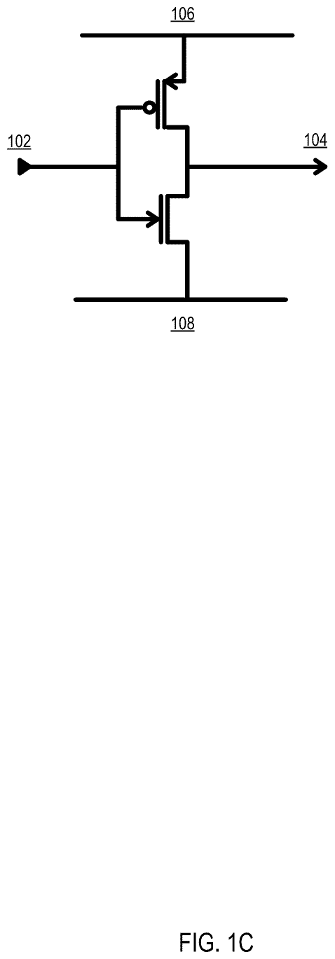

Fabrication as shown in a side view in FIG. 1A begins with the fabrication of the FEOL 101 (Front End Of Line), which includes the manufacture of all MOS transistors. BEOL 103 (Back End Of Line) manufacturing begins after the FEOL fabrication is completed, which comprises the manufacture of metal interconnects. During BEOL manufacture, the antenna effect enters the picture. A top view of the transistor is shown in FIG. 1B with In 102 and Out 104 indicated, and a diagram of the transistor is shown in FIG. 1C with In 102 and Out 104 and VDD or Power 106 and VSS or Ground 108 indicated. Plasma etching is used to produce metal interconnects in the IC manufacturing process. Plasma etching is a selective etching method that is dry and anisotropic. During the etching process of metals, plasma comprises high-energy ions and radicals, which are gathered by metal interconnects. Although the antenna effect in VLSI occurs during the chip fabrication process, particularly during plasma etching, the avoidance mechanism should be established from the physical design stage.

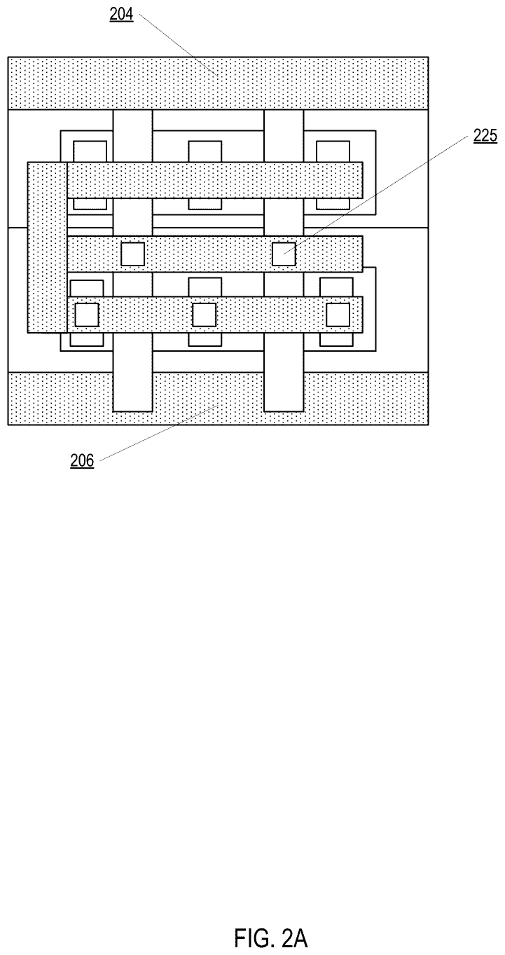

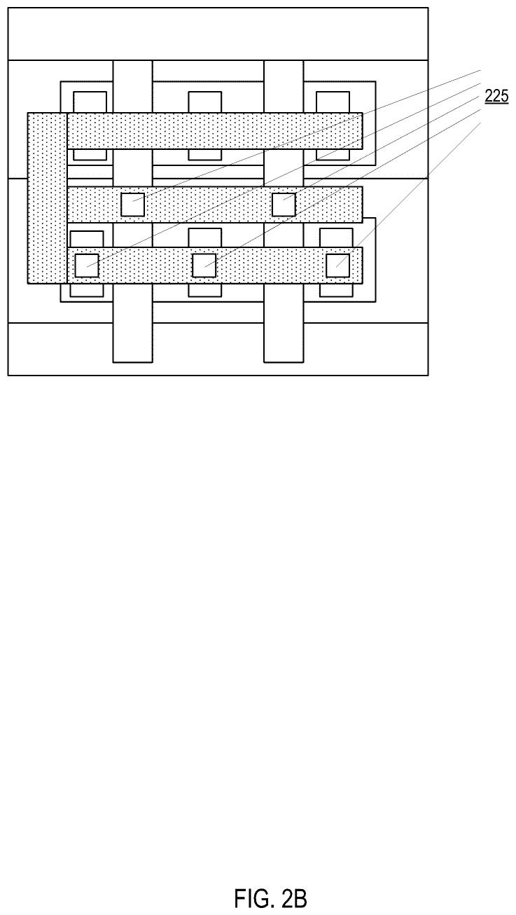

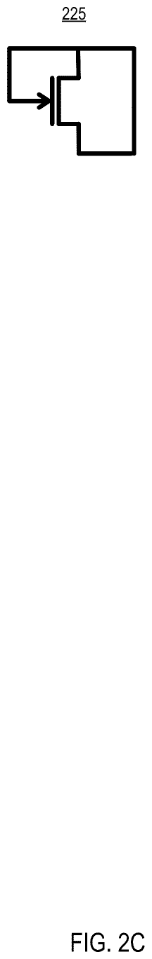

During the physical signoff step, the fabrication laboratory produces an antenna rule file, which places diodes in each IP to protect each gate irrespective of the routing from the higher levels and the driver size. The diodes 225 connecting the source VSS 206 and drain VDD 204 are shown in FIG. 2A and in a simplified view as diodes 225 in FIG. 2B. A diagram of the diode 225 is shown in FIG. 2C. The antenna cell is constructed by connecting the source and drain of the N-channel MOSFET to the same potential. The source and drain of the N-channel FET form a diode with p-substrate and provides a discharge path to the substrate so that built-up charges do not damage the gate.

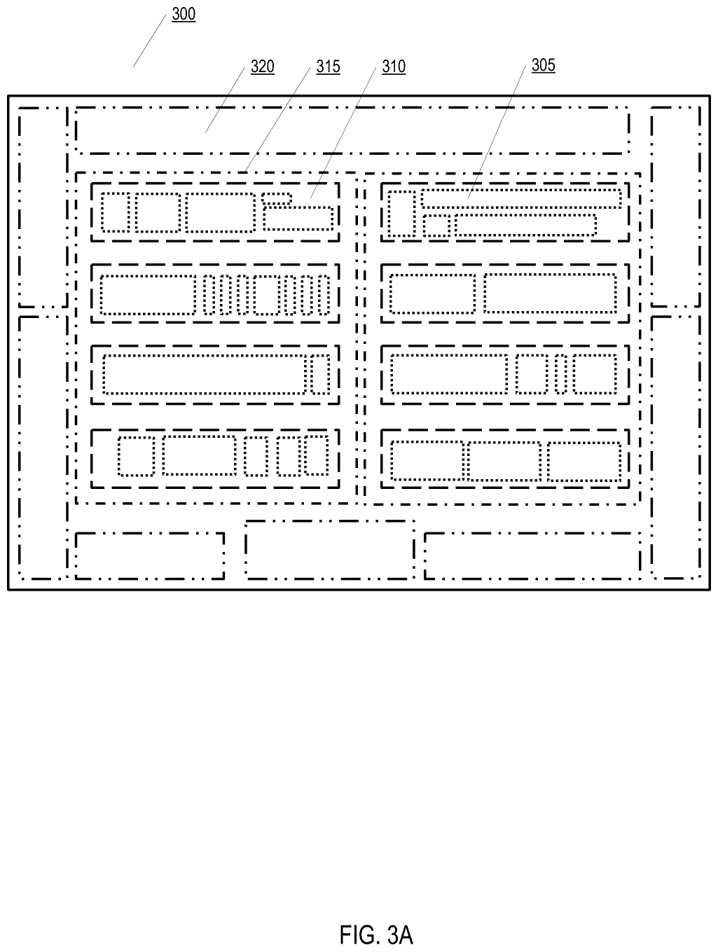

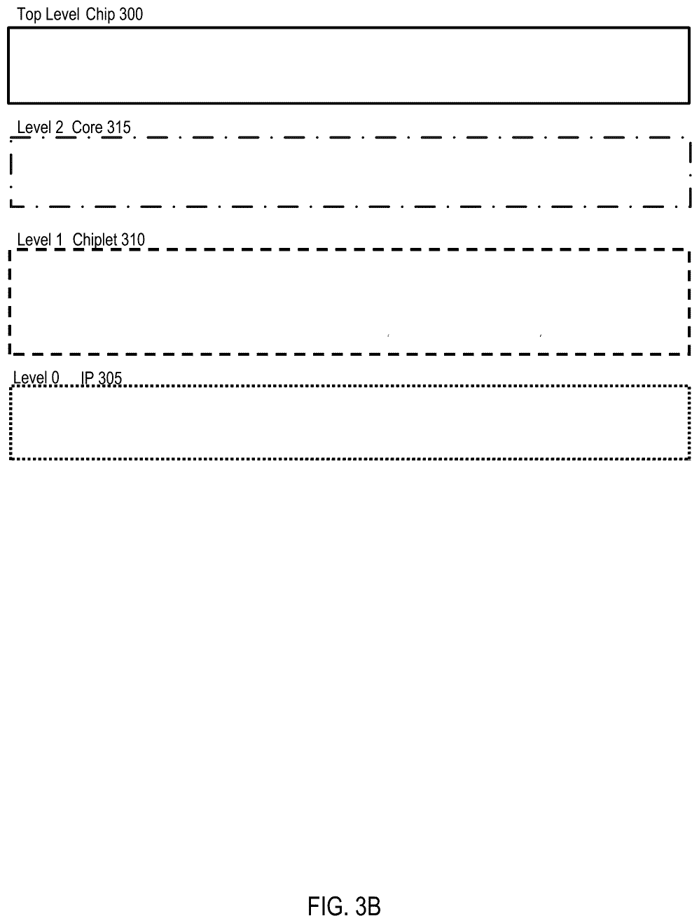

There may be many IP blocks or cores on many chiplets on a chip. An IP block ore core is a reusable unit of logic or functionality or a cell or a layout design that is normally developed with the idea for using and reusing as building blocks in different chip designs. Shown in FIG. 3A, each IP block 305 is on a chiplet 310. The chiplets 310 are on cores 315 which are approximately 60-70% of the chip 300 with I/O (input/output) 320 approximately 20% of the chip 300. Overall, a chip may have 4 to 5 billion transistors, in an exemplary embodiment. In a chip hierarchy shown in FIG. 3B, the chip level 300 is the top level. The core 315 is the next level, the chiplet 310 is the next level, and the IP level 305 is the bottommost level.

Embodiments in accordance with the present disclosure provide a parameterized intellectual property (IP) algorithm for power reduction across a chip hierarchy. Rather than providing fixed diodes for all instances of gates in an IP irrespective of the routing from higher levels and of driver size, a parameterized IP algorithm provides for controlling bottom level devices from higher levels of hierarchy and for controlling diodes for gates to be fully on, partially on, or off according to specific information about each antenna violation. The design will have only required antenna diodes with a minimum of metal mask change. With fewer antenna diodes, there will be less parasitic capacitance resulting in lower power and higher performance.

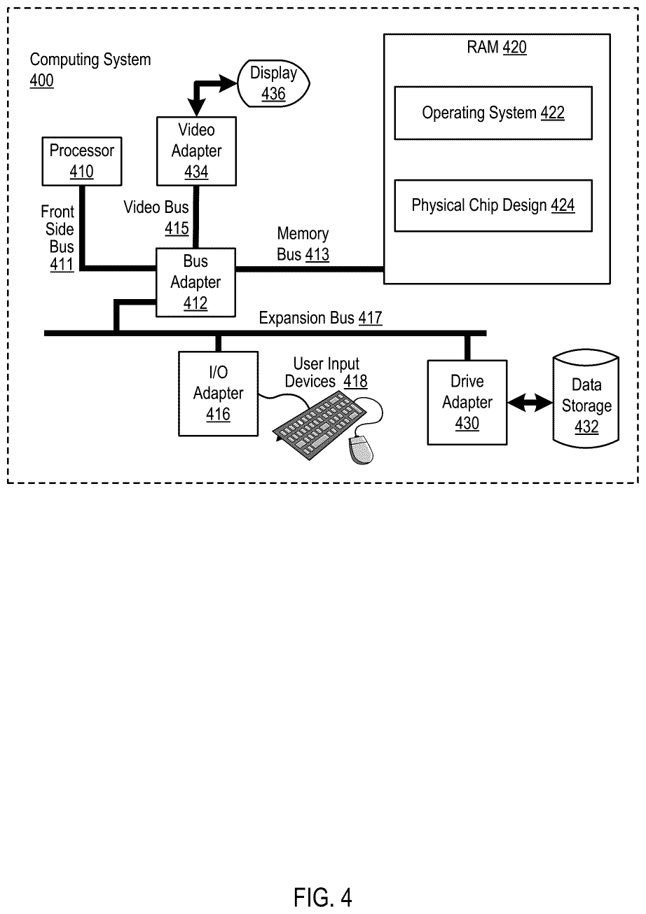

Exemplary apparatus and systems for providing a parameterized intellectual property (IP) algorithm for power reduction across a chip hierarchy in accordance with the present disclosure are described with reference to the accompanying drawings, beginning with FIG. 4. FIG. 4 sets forth a block diagram of automated computing machinery comprising an exemplary computing system 400 configured for providing a parameterized intellectual property (IP) algorithm for power reduction across a chip hierarchy according to embodiments of the present disclosure. The computing system 400 of FIG. 4 includes at least one computer processor 410 or ‘CPU’ as well as random access memory (‘RAM’) 420 which is connected through a high-speed memory bus 413 and bus adapter 412 to processor 410 and to other components of the computing system 400.

Stored in RAM 420 is an operating system 422. Operating systems useful in computers configured for providing dedicated memory assignments to applications according to embodiments of the present disclosure include z/OS™, UNIX™, Linux™. Microsoft Windows™. AIX™, and others as will occur to those of skill in the art. The operating system 422 in the example of FIG. 4 is shown in RAM 420, but many components of such software typically are stored in non-volatile memory also, such as, for example, on data storage 432, such as a disk drive.

Also stored in RAM is a physical chip design 424. The physical chip design 424 is embodied in a set of processor-executable instructions that, when executed by the processor 410, causes the computing system 400 to carry out the steps of for each input pin at a chip hierarchy level, determining a parameterized diode value only for an indication of an antenna violation, wherein a parameterized diode is scaled to protect a gate; and enabling the parameterized diode with the parameterized diode value. The physical chip design 424 is embodied in a further set of processor-executable instructions that, when executed by the processor 410, causes the computing system 400 to carry out the steps of placing a placeholder parameterized diode for each input pin; for each IP, converting the IP into a parameterized IP; and upon a determination of no antenna violation, disabling the parameterized diode.

The computing system 400 of FIG. 4 includes disk drive adapter 430 coupled through expansion bus 417 and bus adapter 412 to processor 410 and other components of the computing system 400. Disk drive adapter 430 connects non-volatile data storage to the computing system 400 in the form of data storage 432. Disk drive adapters useful in computers configured for inserting sequence numbers into editable tables according to embodiments of the present disclosure include Integrated Drive Electronics (‘IDE’) adapters, Small Computer System Interface (‘SCSI’) adapters, and others as will occur to those of skill in the art. Non-volatile computer memory also may be implemented for as an optical disk drive, electrically erasable programmable read-only memory (so-called ‘EEPROM’ or ‘Flash’ memory), RAM drives, and so on, as will occur to those of skill in the art.

The example computing system 400 of FIG. 4 includes one or more input/output (′I/O′) adapters 416. I/O adapters implement user-oriented input/output through, for example, software drivers and computer hardware for controlling output to display devices such as computer display screens, as well as user input from user input devices 418 such as keyboards and mice. The example computing system 400 of FIG. 4 includes a video adapter 434, which is an example of an I/O adapter specially designed for graphic output to a display device 436 such as a display screen or computer monitor. Video adapter 434 is connected to processor 410 through a high speed video bus 415, bus adapter 412, and the front side bus 411, which is also a high speed bus.

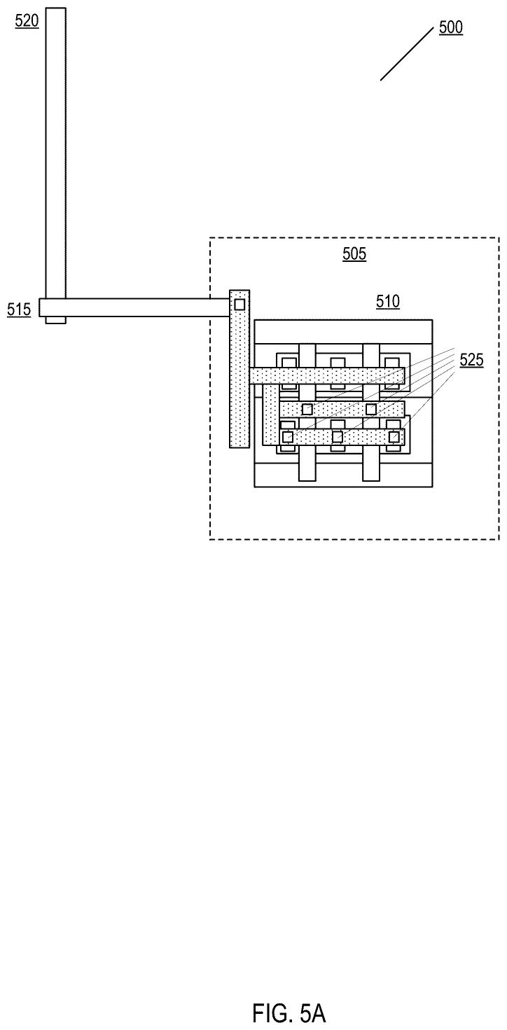

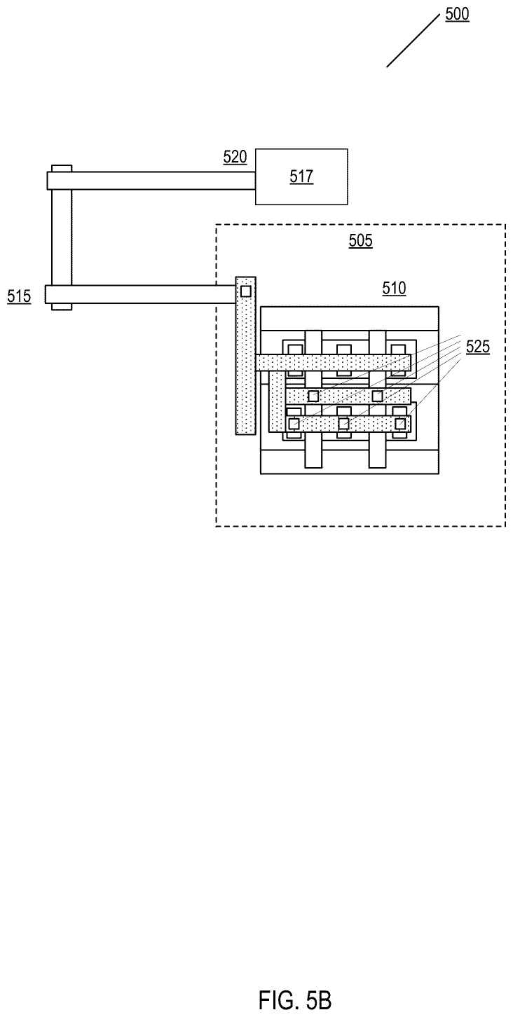

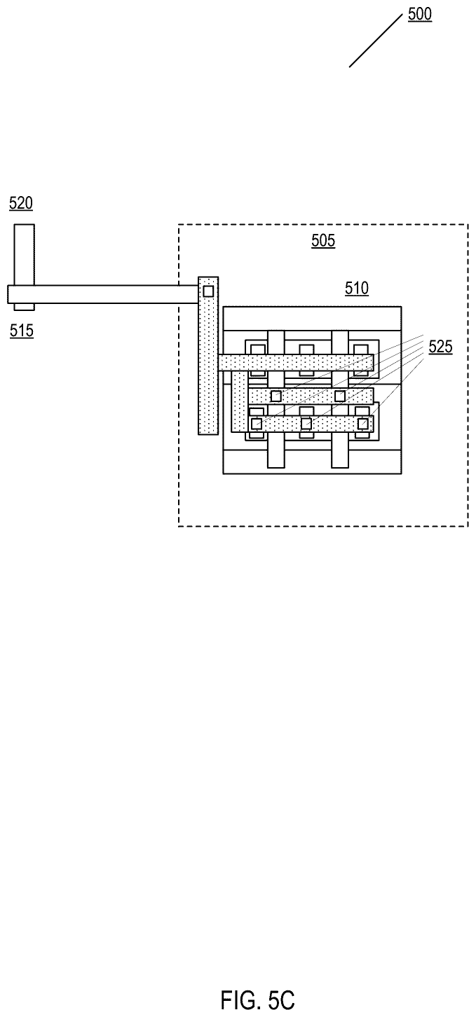

For further reference, FIG. 5A sets forth a block diagram of an example chip design 500 for providing a parameterized intellectual property (IP) algorithm for power reduction across a chip hierarchy in accordance with some embodiments of the present disclosure. The example chip design 500 includes an IP block 505 with circuitry 510 connected by routing 515 to input pin 520. The routing 515 to input pin 520 is long and induces parasitic capacitance and receives an antenna violation during an antenna check. In conventional methodology, antenna diodes 525 are placed in the IP block 505 to protect the gate oxide.

For further reference, FIG. 5B sets forth a block diagram of an example chip design 500 for providing a parameterized intellectual property (IP) algorithm for power reduction across a chip hierarchy in accordance with some embodiments of the present disclosure. Similar to the chip design described hereinabove, the example chip design 500 includes an IP block 505 with circuitry 510 connected by routing 515 to input pin 520. The routing 515 to input pin 520 is an intermediate length but input pin 520 is connected to a large driver 517. In conventional methodology, the routing 515 receives an antenna violation during the antenna check and antenna diodes 525 are placed in the IP block 505 to protect the gate oxide.

For further reference, FIG. 5C sets forth a block diagram of an example chip design 500 for providing a parameterized intellectual property (IP) algorithm for power reduction across a chip hierarchy in accordance with some embodiments of the present disclosure. Similar to the chip design described hereinabove, the example chip design 500 includes an IP block 505 with circuitry 510 connected by routing 515 to input pin 520. The routing 515 to input pin 520 is short. In conventional methodology, the routing 515 receives an antenna violation during the antenna check and antenna diodes 525 are placed in the IP block 505 to protect the gate oxide.

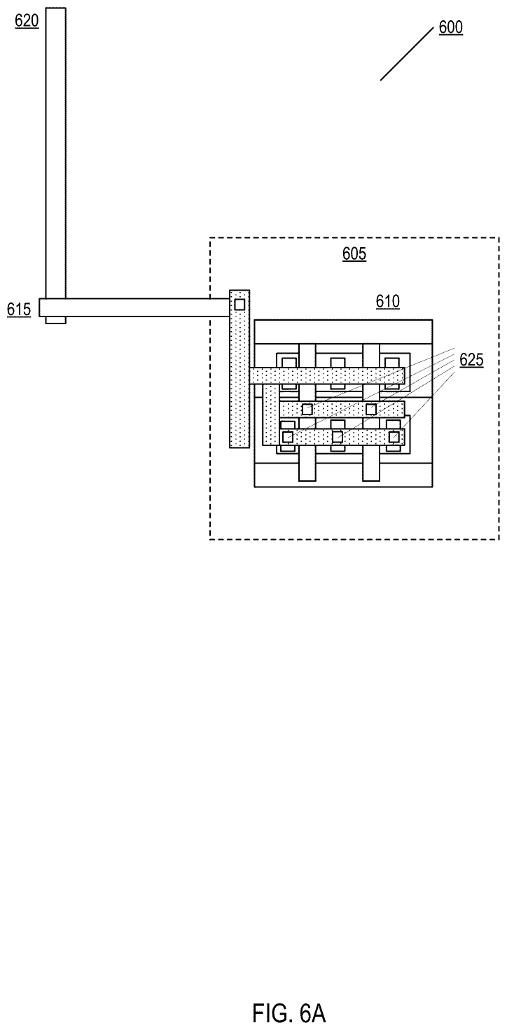

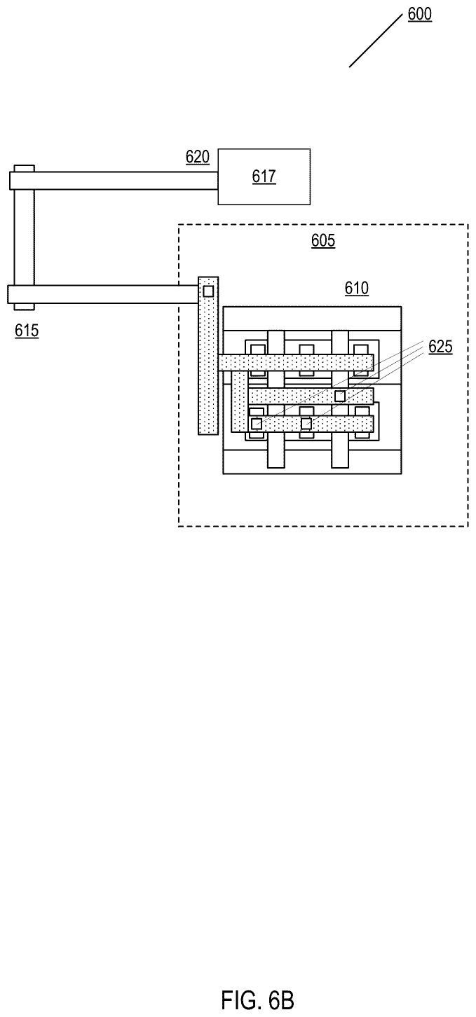

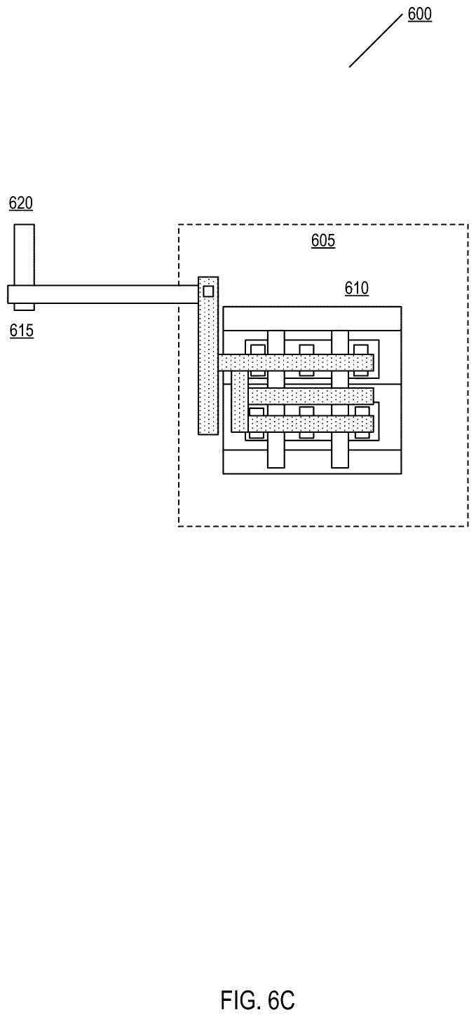

For further reference, FIG. 6A sets forth a block diagram of an example chip design 600 for providing a parameterized intellectual property (IP) algorithm for power reduction across a chip hierarchy in accordance with some embodiments of the present disclosure. The example chip design 600 includes an IP block 605 with circuitry 610 connected by routing 615 to input pin 620. The routing 615 to input pin 620 is long and induces parasitic capacitance and receives an antenna violation during an antenna check. As in the chip design described hereinabove, antenna diodes 625 are placed in the IP block 605 to protect the gate oxide.

For further reference, FIG. 6B sets forth a block diagram of an example chip design 600 for providing a parameterized intellectual property (IP) algorithm for power reduction across a chip hierarchy in accordance with some embodiments of the present disclosure. Similar to the chip design described hereinabove, the example chip design 600 includes an IP block 605 with circuitry 610 connected by routing 615 to input pin 620. The routing 615 to input pin 620 is an intermediate length but input pin 620 is connected to a large driver 617. Using a parameterized IP algorithm, the routing 515 receives a partial antenna violation during the antenna check and partial antenna diodes 525 are placed in the IP block 605 to protect the gate oxide.

For further reference, FIG. 6C sets forth a block diagram of an example chip design 600 for providing a parameterized intellectual property (IP) algorithm for power reduction across a chip hierarchy in accordance with some embodiments of the present disclosure. Similar to the chip design described hereinabove, the example chip design 600 includes an IP block 605 with circuitry 610 connected by routing 615 to input pin 620. The routing 615 to input pin 620 is short. Using a parameterized IP algorithm, the routing 615 does not receive an antenna violation during the antenna check and no antenna diodes are placed in the IP block 605.

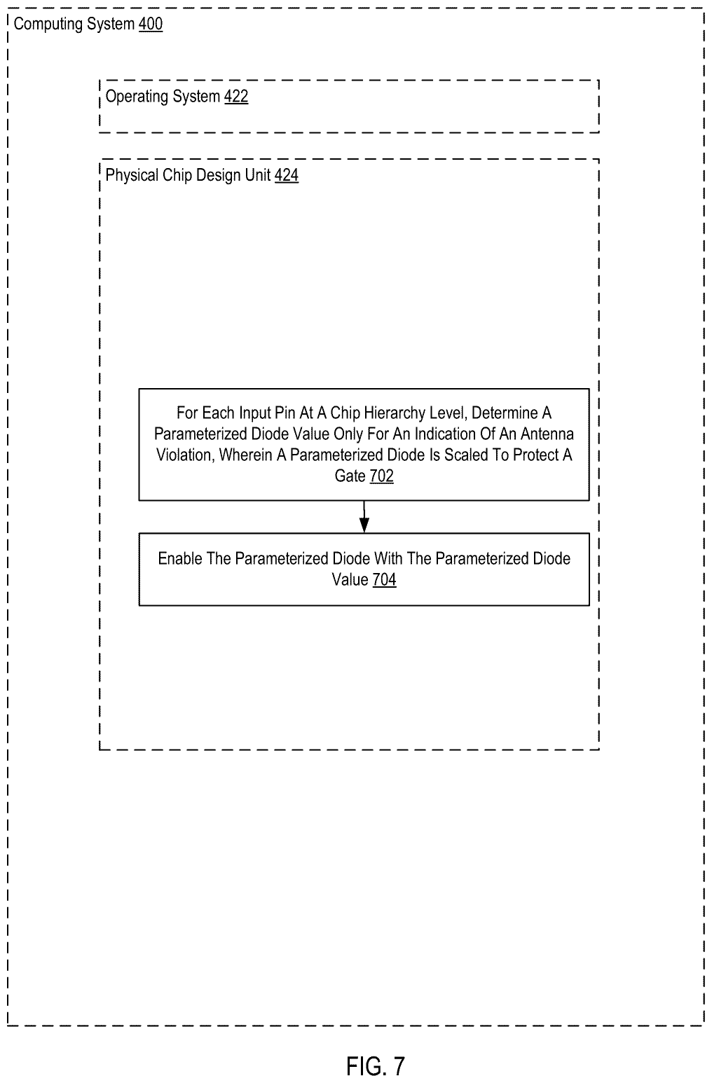

For further explanation, FIG. 7 sets forth a flowchart illustrating an example method of providing a parameterized intellectual property (IP) algorithm for power reduction across a chip hierarchy according to embodiments of the present disclosure. During the physical layout design, routing, and verification of a chip, such as chip 600 of FIGS. 6A-6C, the method of FIG. 7 includes, for each input pin at a chip hierarchy level, determining 702 a parameterized diode value only for an indication of an antenna violation, wherein a parameterized diode is scaled to protect a gate. A parameterized diode is an antenna diode that is scalable or tunable and can be configured to different values and has a parameterized diode value. For each input pin at a chip hierarchy level, determining 702 a parameterized diode value only for an indication of an antenna violation, wherein a parameterized diode is scaled to protect a gate, includes running a design rule check (DRC) to verify the design meets manufacturing and fabrication constraints. For each input pin at each chip hierarchy level, such as the IP level, chiplet level, core level, and chip level, the DRC rules will use specific information about the length of the routing and any information about a driver. Each input pin at the lowest level, the IP level, is DRC checked for an antenna violation, and then each input pin at the next higher level such as the chiplet level is DRC checked for an antenna violation, and then each input pin at the next higher level such as the core level is DRC checked for an antenna violation, and pin at the next level, the highest level, such as the core level, is DRC checked for an antenna violation. As shown above in FIGS. 6A-6C, input pins with long routing wires will receive an indication of an antenna violation while input pins with short routing will not receive an indication of an antenna violation and input pins with intermediate length routing and strong drivers will receive an indication of a partial antenna violation. For the input pins receiving an antenna violation or a partial antenna violation, a parameterized diode value is determined to scale to protect the gate oxide, from full size to partial size.

The method of FIG. 7 also includes enabling 704 the parameterized diode with the parameterized diode value. Enabling 704 the parameterized diode with the parameterized diode value includes enabling each parameterized diode with the parameterized diode value for each input pin with an antenna violation or partial antenna violation. Each IP with an antenna violation or partial antenna violation will have a scaled or tuned antenna diode to protect the gate. As described above, input pins with long routing wires have an indication of an antenna violation and the parameterized diode with its parameterized diode value is enabled, and input pins with intermediate length routing and strong drivers have an indication of a partial antenna violation and the parameterized diode with its parameterized diode value is enabled, while input pins with short routing do not have an indication of an antenna violation. In this way, the antenna diodes can be controlled from the IP layer and also from higher levels of hierarchy.

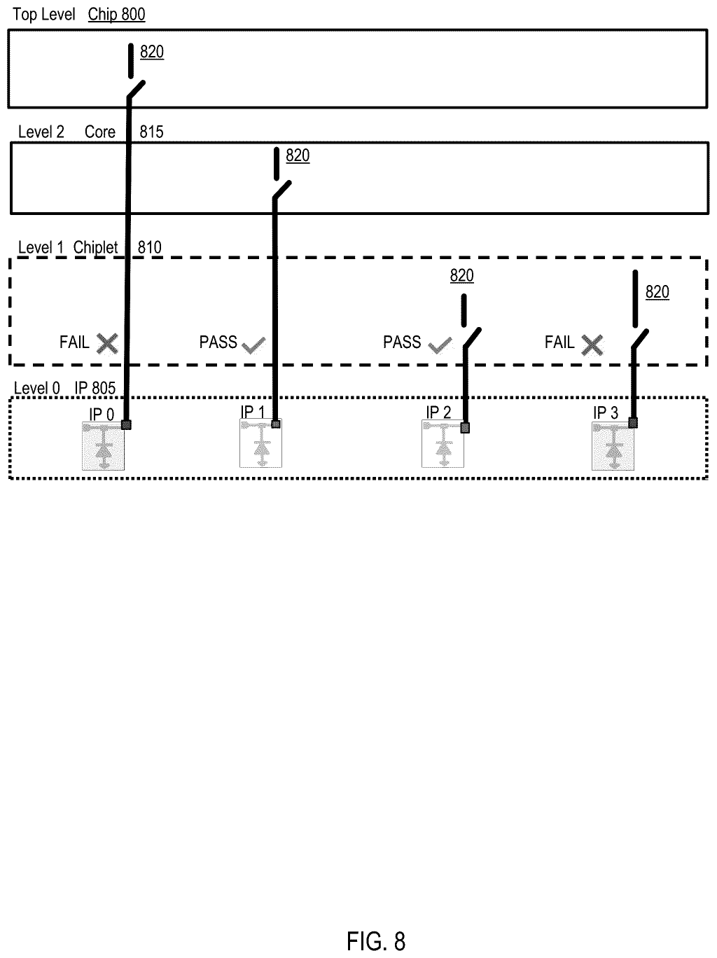

For further reference, FIG. 8 sets forth a block diagram of a chip hierarchy for providing a parameterized intellectual property (IP) algorithm for power reduction across a chip hierarchy according to embodiments of the present disclosure. In a chip hierarchy shown in FIG. 8, similar to the chip hierarchy described hereinabove with reference to FIG. 3B, the chip level 800 is the top level. The core 815 is the next level, the chiplet 810 is the next level, and the IP level 805 is the bottommost level. Also shown in FIG. 8 are IP 0, IP 2, IP 2, and IP3 which are IP blocks similar in design to circuits in FIGS. 6A, 6B, and 6C. During the physical layout design, routing, and verification of the chip, for each input pin at the chip hierarchy level, a parameterized diode value 625 is determined 702 only for an indication of an antenna violation, wherein a parameterized diode is scaled to protect a gate. For IP 3, there is an antenna violation 820 and the parameterized diode 625 is enabled 704 from the chiplet level. For IP 2, there is no antenna violation 820 so there are no antenna diodes enabled. For IP 1, there is no antenna violation 820 so there are no antenna diodes enabled. For IP 0, there is an antenna violation 820 and the parameterized diode 625 is enabled 704 from the top level, the chip level. As shown in FIG. 8, the antenna diodes can be controlled from the IP level and also from higher levels of hierarchy.

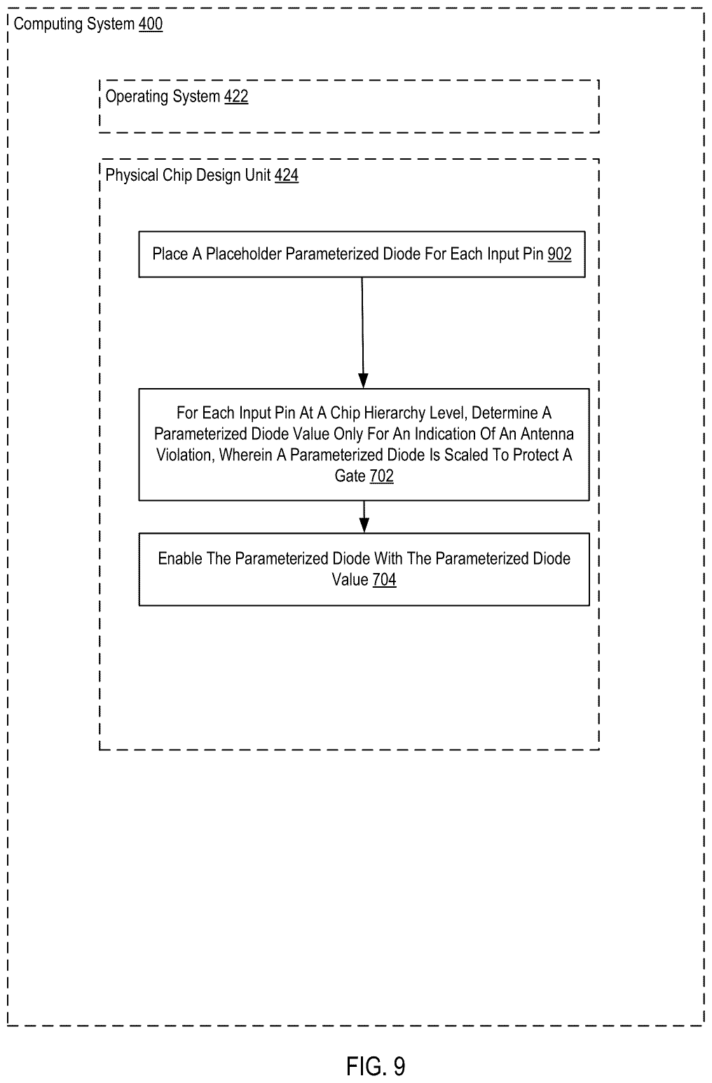

For further reference, FIG. 9 sets forth a flow chart of another example method of providing a parameterized intellectual property (IP) algorithm for power reduction across a chip hierarchy in accordance with some embodiments of the present disclosure. The method of FIG. 9 extends the method of FIG. 7 in that the method of FIG. 9 further includes placing 902 a placeholder parameterized diode for each input pin. During the physical layout design, routing, and verification of the chip, for each input pin, a placeholder parameterized diode is placed. The placeholder parameterized diode is used during layout design and routing and is enabled 704 during verification after the DRC check finds an antenna violation.

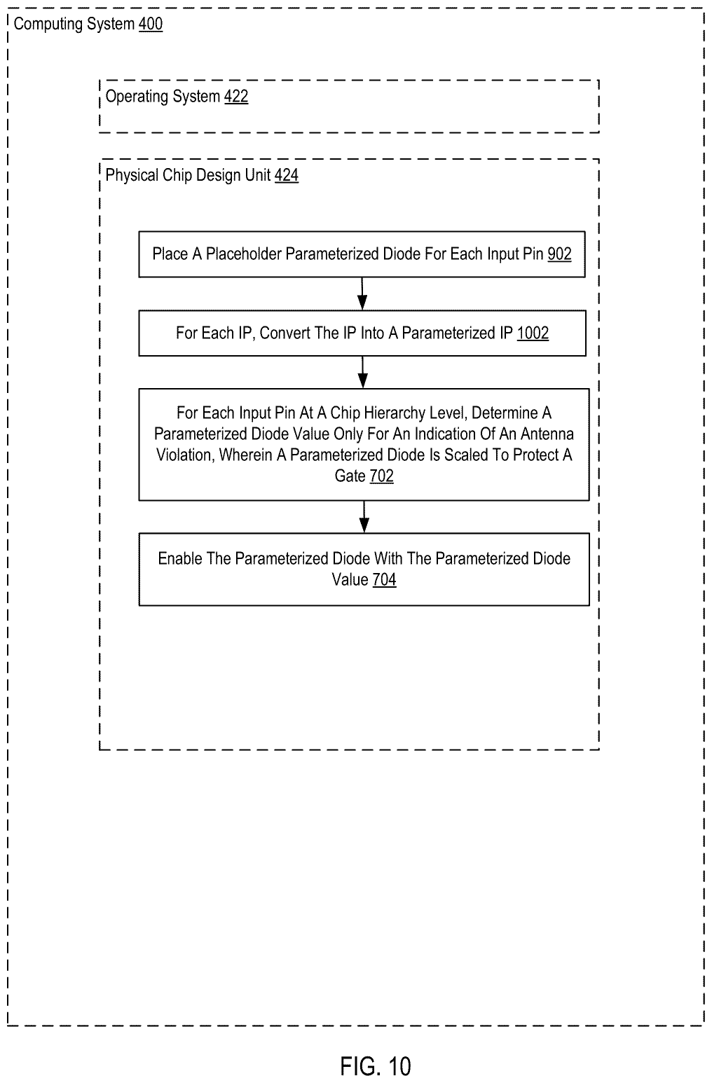

For further reference, FIG. 10 sets forth a flow chart of another example method of providing a parameterized intellectual property (IP) algorithm for power reduction across a chip hierarchy in accordance with some embodiments of the present disclosure. The method of FIG. 10 extends the method of FIG. 9 in that the method of FIG. 10 further includes for each IP, converting 1002 the IP into a parameterized IP. During the physical layout design, routing, and verification of the chip, for each IP, the IP is converted from an “as supplied IP” into a parameterized IP with parameters that can be configured. Using a parameterized IP algorithm to tune a parameterized IP and parameterized antenna diode allows for optimized area use, power consumption, and performance.

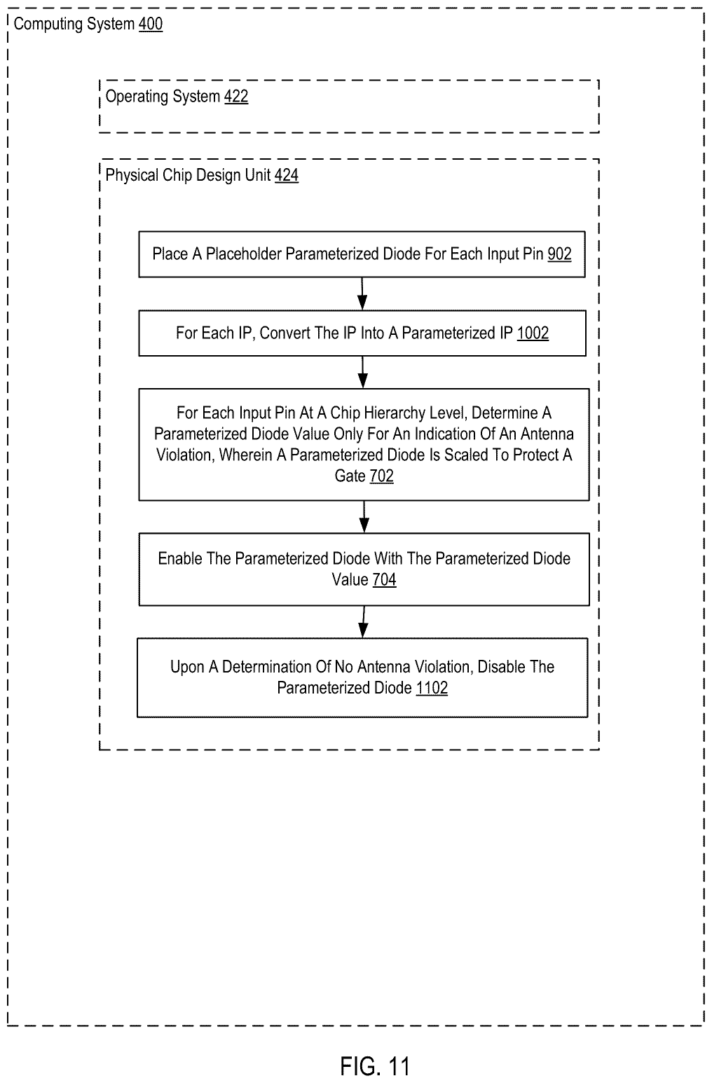

For further reference, FIG. 11 sets forth a flow chart of another example method of providing a parameterized intellectual property (IP) algorithm for power reduction across a chip hierarchy in accordance with some embodiments of the present disclosure. The method of FIG. 11 extends the method of FIG. 10 in that the method of FIG. 11 further includes upon a determination of no antenna violation, disabling 1102 the parameterized diode. As described above, during the physical layout design, routing, and verification of a chip, such as chip 600 of FIGS. 6A-6C, for each input pin at a chip hierarchy level, upon a determination of no antenna violation, disabling 1102 the parameterized diode. For each input pin at a chip hierarchy level, a design rule check (DRC) is run to verify the design meets manufacturing and fabrication constraints. For each input pin at each chip hierarchy level, such as the IP level, chiplet level, core level, and chip level, the DRC rules will use specific information about the length of the routing and any information about a driver. Each input pin at the lowest level, the IP level, is DRC checked for an antenna violation, and then each input pin at the next higher level such as the chiplet level is DRC checked for an antenna violation, and then each input pin at the next higher level such as the core level is DRC checked for an antenna violation, and pin at the next level, the highest level, such as the core level, is DRC checked for an antenna violation. As shown above in FIGS. 6A-6C, input pins with long routing wires will receive an indication of an antenna violation while input pins with short routing will not receive an indication of an antenna violation and input pins with intermediate length routing and strong drivers will receive an indication of a partial antenna violation. For input pins with short routing and no antenna violation, the parameterized diode is disabled 1102.

In an example embodiment, the method of FIGS. 7 and 9-11 is an iterative process. At the IP level, a placeholder parameterized diode is placed 902 and the IP is converted to a parameterized IP. Then routing is completed at the next higher level of the chiplet level and a DRC check is run. Upon a determination of an antenna violation based upon specific characteristics of the length of routing and strength of any drivers, a parameterized diode value is determined 702 and the parameterized diode is enabled 704 or, if no antenna violation is determined, the parameterized diode is disabled 1102. The method continues at the next hierarchy level of completing the routing at the core level and then running a DRC check to determine if there are any antenna violations based upon specific characteristics of the length of routing and strength of any drivers. Upon a determination of an antenna violation, a parameterized diode value is determined 702 and the parameterized diode is enabled 704 or, if no antenna violation is determined, the parameterized diode is disabled 1102. The method continues at the next hierarchy of completing the routing at the topmost chip level and then running a DRC check to determine if there are any antenna violations. Upon a determination of an antenna violation based upon specific characteristics of the length of routing and strength of any drivers, a parameterized diode value is determined 702 and the parameterized diode is enabled 704 or, if no antenna violation is determined, the parameterized diode is disabled 1102. In this way, the antenna diodes can be controlled and tuned from the IP layer and also from higher levels of hierarchy.

In view of the explanations set forth above, readers will recognize a number of advantages of providing a parameterized intellectual property (IP) algorithm for power reduction across a chip hierarchy according to embodiments of the present disclosure including:
Providing a parameterized intellectual property (IP) algorithm for power reduction and reduced capacitance and higher performance.
Providing a parameterized intellectual property (IP) algorithm for increased area and minimum metal mask change.
Providing a parameterized intellectual property (IP) algorithm for control of bottom level devices from higher levels in the chip hierarchy.

Exemplary embodiments of the present disclosure are described largely in the context of a fully functional computer system for optimizing network load in multicast communications. Readers of skill in the art will recognize, however, that the present disclosure also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the disclosure as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present disclosure.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method for providing a parameterized IP algorithm for power reduction across a chip hierarchy, the method comprising:
for each input pin at a chip hierarchy level, determining a parameterized diode value only for an indication of an antenna violation, wherein a parameterized diode is scaled to protect a gate; and
enabling the parameterized diode with the parameterized diode value.

2. The method of claim 1 further comprising:
placing a placeholder parameterized diode for each input pin.

3. The method of claim 1 further comprising:
for each IP, converting the IP into a parameterized IP.

4. The method of claim 1 further comprising:
upon a determination of no antenna violation, disabling the parameterized diode.

5. The method of claim 1 wherein the determination is made for each input pin at an IP level.

6. The method of claim 1 wherein the parameterized diode value is scaled to be less than full sized.

7. An apparatus for providing a parameterized IP algorithm for power reduction across a chip hierarchy, the apparatus comprising a computer processor, a computer memory operatively coupled to the computer processor, the computer memory having disposed within it computer program instructions that, when executed by the computer processor, cause the apparatus to carry out the steps of:
for each input pin at a chip hierarchy level, determining a parameterized diode value only for an indication of an antenna violation, wherein a parameterized diode is scaled to protect a gate; and
enabling the parameterized diode with the parameterized diode value.

8. The apparatus of claim 7, further comprising:
placing a placeholder parameterized diode for each input pin.

9. The apparatus of claim 7, further comprising:
for each IP, converting the IP into a parameterized IP.

10. The apparatus of claim 7, further comprising:
upon a determination of no antenna violation, disabling the parameterized diode.

11. The apparatus of claim 7 wherein the determination is made for each input pin at an IP level.

12. The apparatus of claim 7 wherein the parameterized diode value is scaled to be less than full sized.

13. A computer program product for providing a parameterized IP algorithm for power reduction across a chip hierarchy, the computer program product disposed upon a computer readable medium, the computer program product comprising computer program instructions that, when executed, cause a computer to carry out the steps of:
for each input pin at a chip hierarchy level, determining a parameterized diode value only for an indication of an antenna violation, wherein a parameterized diode is scaled to protect a gate; and
enabling the parameterized diode with the parameterized diode value.

14. The computer program product of claim 13 further comprising:
placing a placeholder parameterized diode for each input pin.

15. The computer program product of claim 13 further comprising:
for each IP, converting the IP into a parameterized IP.

16. The computer program product of claim 13 further comprising:
upon a determination of no antenna violation, disabling the parameterized diode.

17. The computer program product of claim 13 wherein the determination is made for each input pin at an IP level.

18. The computer program product of claim 13 wherein the parameterized diode value is scaled to be less than full sized.

19. The computer program product of claim 13 wherein the computer readable medium comprises a storage medium.
